(19) United States
(12) Patent Application Publication
(10) Pub. No.: US 2011/0049702 A1
(43) Pub. Date: Mar. 3, 2011

(54) SEMICONDUCTOR PACKAGE AND METHOD OF PRODUCING THE SAME

(75) Inventor: Syuji NEGORO, Nagano-shi (JP)

(73) Assignee: SHINKO ELECTRIC INDUSTRIES CO., LTD.

(21) Appl. No.: 12/861,008

(22) Filed: Aug. 23, 2010

(30) Foreign Application Priority Data
Aug. 26, 2009 (JP) 2009-195737

(51) Int. Cl. H01L 23/36; H01L 21/60; H01L 23/488

(52) U.S. Cl. 257/720; 438/122; 257/E21.499; 257/E21.509; 257/E23.101; 257/E23.023

(57) ABSTRACT

A method of producing a semiconductor package includes setting a radiator member on a semiconductor device that is mounted on a wiring board, said radiator member having a convex surface part on at least a part of a first surface thereof opposite to a second surface thereof to be bonded to the semiconductor device, and pressing the convex surface part of the radiator member towards the semiconductor device in order to align the radiator member and the semiconductor device automatically and to become substantially parallel to each other.

### CROSS-REFERENCE TO RELATED APPLICATIONS

This application is based upon and claims the benefit of priority of the prior Japanese Patent Application No. 2009-195737, filed on Aug. 26, 2009, the entire contents of which are incorporated herein by reference.

### BACKGROUND OF THE INVENTION

1. Field of the Invention

The present invention relates to semiconductor packages and methods of producing (or fabricating) the same.

2. Description of the Related Art

A semiconductor package that is mounted with semiconductor devices may be mounted on a wiring board, a mother board and the like for use in electronic equipments. The semiconductor package is used in various fields including information processing and communication. In order to radiate heat generated from the semiconductor device during operation, the semiconductor package itself is provided with a heat radiation function to release heat. In the semiconductor package having the semiconductor device directly bonded on the wiring board by flip-chip bonding, a radiator plate is often provided on a back surface of the semiconductor device to radiate heat. The radiator plate may be referred to as a heat slug or a heat spreader, and a metal material or the like having a relatively high heat conduction is used to form the radiator plate.

FIGS. 1A through 1C are cross sectional views for explaining examples of a conventional semiconductor package having a radiator plate.

FIG. 1A illustrates a semiconductor package 100-1 including a substrate 16, a semiconductor device 11, and a radiator plate 14. The radiator plate 14 has a recess 12 for accommodating a semiconductor device 11. The radiator plate 14 is for radiating from a surface thereof the heat generated from the semiconductor device 11 and transferred via thermal grease 13. The radiator plate 14 is fixed to the substrate 16 using a bonding agent 15. A surface 16a of the substrate 16, opposite to the surface mounted with the semiconductor device 11, is provided with connection terminals 17 having solder balls 18 formed thereon. The connection terminals 17 and the solder balls 18 form external connection terminals for connecting the semiconductor package 100-1 to a wiring board, a mother board or the like.

FIG. 1B illustrates a semiconductor package 100-1 including a substrate 20 with a cavity 19 for accommodating the semiconductor device 11, and a radiator plate 21. In FIG. 1B, those parts that are the same as those corresponding parts in FIG. 1A are designated by the same reference numerals, and a description thereof will be omitted.

FIG. 1C illustrates a semiconductor package 100-3 including a substrate 23 with a cavity for accommodating the semiconductor device 11 and a radiator plate 24. In FIG. 1C, those parts that are the same as those corresponding parts in FIG. 1A are designated by the same reference numerals, and a description thereof will be omitted. Regions of the cavity, other than regions occupied by the semiconductor device 11 and the radiator plate 24, are filled by a filler material 22. An example the semiconductor package 100-3 is proposed in a Japanese Laid-Open Patent Publication No. 2004-523128.

FIG. 2 is a side view illustrating an example of a conventional apparatus for aligning and bonding a radiator plate 26 and a semiconductor device 11. This apparatus carries out the alignment or, correcting of parallelism, as follows. That is, a sensor 27 measures a distance between a back surface 11b of the semiconductor device 11 and a surface 26a of the radiator plate 26 opposing the back surface 11b, in order to detect the degree of parallelism between the surfaces 11b and 26a. The distance measurement may be made optically, for example. Based on the results of the measurement, a parallelism correcting mechanism 28 controls the position of the radiator plate 26, and sets the degree of parallelism between the surfaces 11b and 26a to a predetermined value before bonding the radiator plate 26 onto the semiconductor device 11. An air bearing or the like may be used for a slider mechanism of the parallelism correcting mechanism 28, as proposed in a Japanese Laid-Open Patent Publication No. 2006-049732, for example.

Conventionally, when assembling the semiconductor package having the radiator plate, the parallelism between the back surface of the semiconductor device and the opposing surface of the radiator plate must be maintained. For this reason, a complex mechanism or apparatus is required to produce the semiconductor package, and complex processes must consequently be carried out. As a result, it may be difficult to simplify the production processes or, to reduce the production cost or, to improve the quality of the semiconductor package that is produced.

### SUMMARY OF THE INVENTION

Accordingly, it is a general object of the present invention to provide a novel and useful semiconductor package and method of producing the same, in which the problem described above may be suppressed.

Another and more specific object of the present invention is to provide a semiconductor package and a method of producing the same, which may simplify the production processes or, reduce the production cost or, improve the quality of the semiconductor package that is produced.

According to one aspect of the present invention, there is provided a method of producing a semiconductor package, comprising setting a radiator member on a semiconductor device that is mounted on a wiring board, the radiator member having a convex surface part on at least a part of a first surface thereof opposite to a second surface thereof to be bonded to the semiconductor device; and pressing the convex surface part of the radiator member towards the semiconductor device in order to align the radiator member and the semiconductor device automatically and to become substantially parallel to each other.

According to one aspect of the present invention, there is provided a semiconductor package comprising a wiring board; a semiconductor device mounted on the wiring board; and a radiator member provided on the semiconductor device, wherein the radiator member includes a convex surface part on at least a part of a first surface thereof opposite to a second surface thereof bonded to the semiconductor device.

Other objects and further features of the present invention will be apparent from the following detailed description when read in conjunction with the accompanying drawings.

### BRIEF DESCRIPTION OF THE DRAWINGS

FIGS. 1A through 1C are cross sectional views for explaining examples of a conventional semiconductor package having a radiator plate;

FIG. 2 is a side view illustrating an example of a conventional apparatus for aligning and bonding a radiator plate 26 and a semiconductor device;

FIGS. 3A through 3D are diagrams for explaining a radiator member in a first embodiment of the present invention;

FIGS. 4A through 4C are cross sectional views for explaining a radiator member in a second embodiment of the present invention;

FIGS. 5A and 55 are side views for explaining an automatic alignment in a third embodiment of the present invention;

FIG. 6 is a flow chart for explaining a method of producing the semiconductor package in the third embodiment of the present invention;

FIG. 7 is a cross sectional view illustrating a semiconductor package in a fourth embodiment of the present invention; and

FIG. 8 is a side view for explaining the automatic alignment in a fifth embodiment of the present invention.

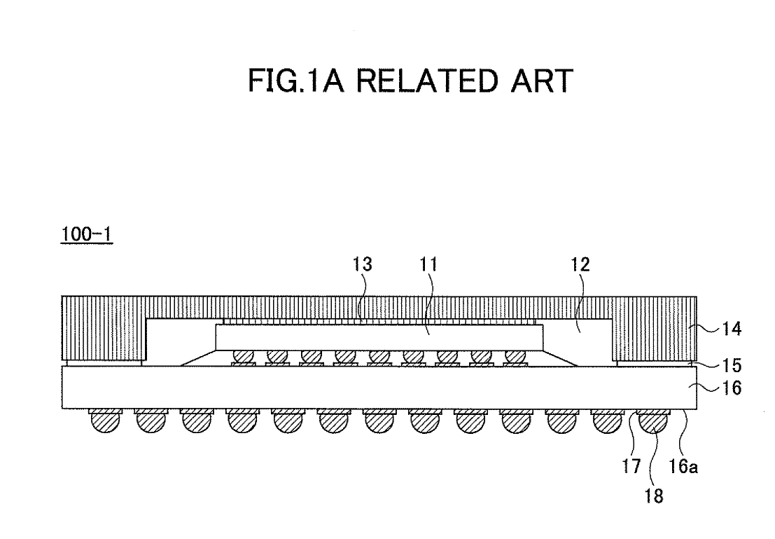

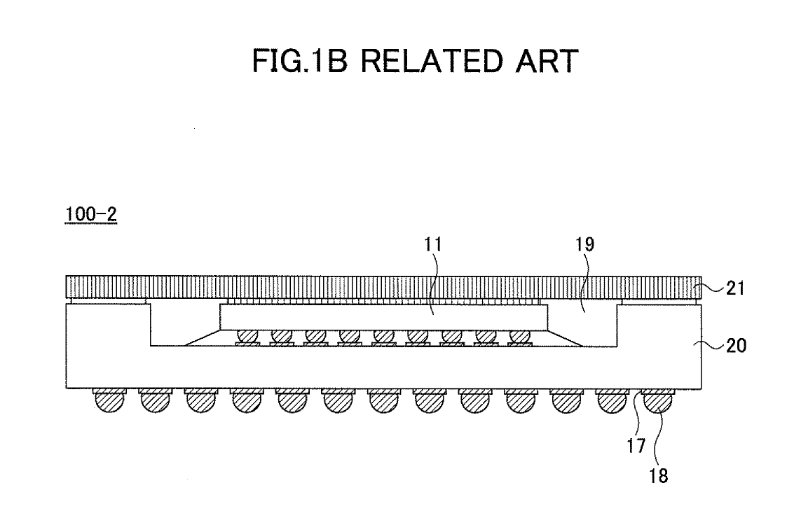

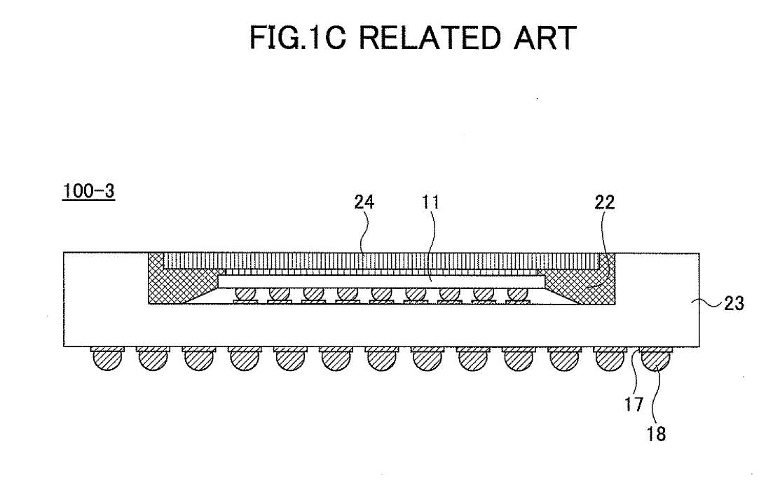

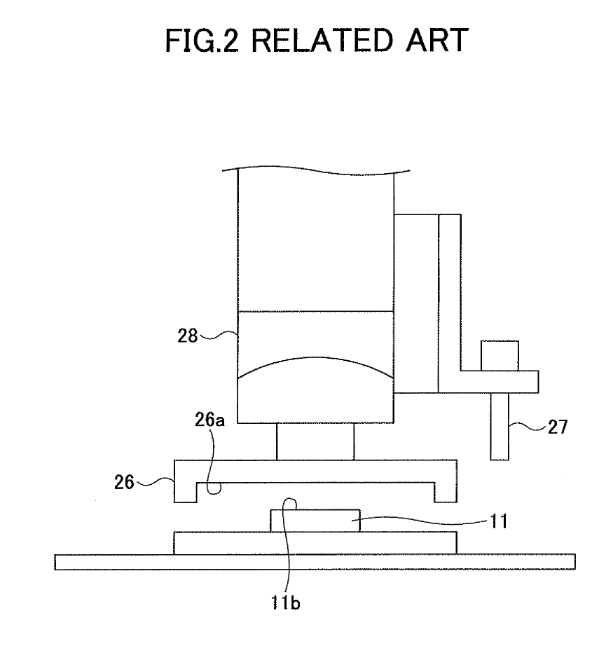

### DESCRIPTION OF THE PREFERRED EMBODIMENTS

### First Embodiment

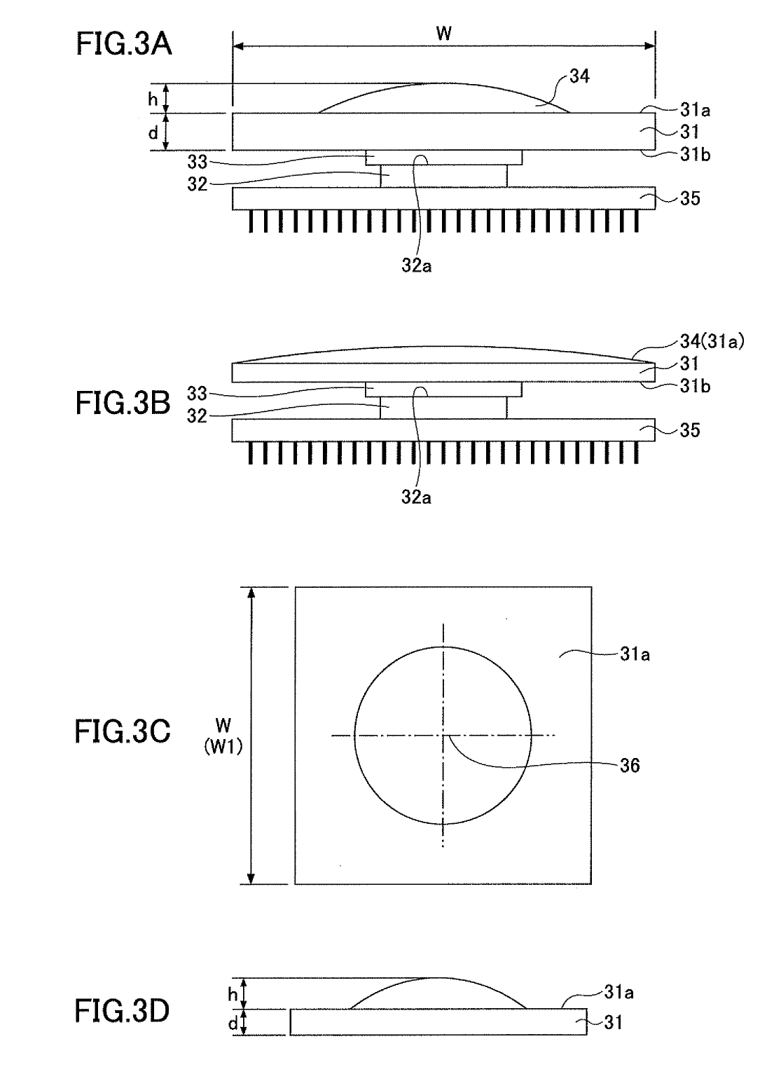

FIGS. 3A through 3D are diagrams for explaining a radiator member in a first embodiment of the present invention.

In this embodiment, a bonding surface 31b of a radiator member (or radiator plate) 31, opposing a semiconductor device 32, is bonded to a back surface 32a of the semiconductor device 32 via a bonding layer 33. The radiator member 31 has a radiating surface 31a opposite to the bonding surface 31b. A smooth convex surface part 34 is formed in at least a portion of the radiating surface 31a. In other words, the smooth convex surface part 34 may be formed on the entire radiating surface 31a. The smooth convex surface part 34 may be formed by an arbitrary curved surface, including a semispherical surface, having a peak (or apex). This peak may be provided in a central region of the radiating surface 31a. Of course, a peripheral region surrounding the peak of the smooth convex surface part 34 may have a concave shape.

In a semiconductor package requiring heat radiation for releasing the heat outside the semiconductor package, the heat radiation efficiency may be improved by maintaining the parallelism between the semiconductor device and the radiator member to a predetermined value. Hence, in this embodiment, the smooth convex surface part 34 of the radiator member 31 may be used to automatically align the bonding surface 31b of the radiator member 31 and the back surface 32a of the semiconductor device 32.

FIG. 3A is a side view illustrating a first example in which a portion of the radiating surface 31a of the radiator member 31 forms the smooth convex surface part 34. In this example, the central portion of the radiating surface 31a forms the smooth convex surface part 34, and a peripheral portion of the radiating surface 31a forms a flat surface.

FIG. 3B is a side view illustrating a second example in which the entire radiating surface 31a of the radiator member 31 forms the smooth convex surface part 34.

The automatic alignment of the bonding surface 31b of the radiator member 31 and the back surface 32a of the semiconductor device 32 will be described later in more detail in conjunction with a third embodiment.

The bonding layer 33 may be formed by a TIM (Thermal Interface Material) such as resins, including silicon polymer resins. The TIM is not limited to resins, and may include metals such as indium, alloys such as indium alloys, carbon-containing resins, and carbon-containing metals or alloys.

FIGS. 3C and 3D respectively are a plan view and a side view illustrating the radiator member 31 illustrated in FIG. 3A. In the example illustrated in FIG. 3C, the radiator member 31 has a square shape having a side W that is 15 mm to 60 mm or, a rectangular shape having a longer side W1 that is 15 mm to 60 mm, for example. The radiator plate 31 has a thickness d of 1 mm to 3 mm, for example. A height h of the peak of the smooth convex surface part 34 relative to the radiating surface 31a of the radiator member 31 is 40 μm, for example, if the square shape has the side W that is 40 mm.

The radiator member 31 may be made of any sufficiently thermally conductive material. For example, the sufficiently thermally conductive material includes OFC (Oxygen-Free Copper) C1020, silver, aluminum, and alloys of any of such metals.

The radiator member 31 may be formed by a suitable known process, including a forging, cutting, and machining processes.

In FIGS. 3A and 3B, the semiconductor device 32 is mounted on a wiring board 35. The wiring board 35 is formed by a PGA (Pin Grid Array) in these examples. However, the wiring board 35 is of course not limited to the PGA, and boards having other formats may be used, including a LGA (Land Grid Array) and a BGA (Ball Grid Array). In addition, the wiring board 35 may be formed by a mother board or the like that is often used in electronic equipments.

In a gap between the radiator member 31 and the wiring board 35, other semiconductor devices, such as chip capacitors and passive devices or passive parts, may be mounted on the upper surface of the wiring board 35 in each of FIGS. 3A and 3B.

According to this first embodiment, the smooth convex surface part 34 of the radiator member 31 may be used to automatically align the bonding surface 31b of the radiator member 31 and the back surface 32a of the semiconductor device 32 when producing the semiconductor package. Because the parallelism between the bonding surface 31b of the radiator member 31 and the back surface 32a of the semiconductor device 32 may easily be secured, the effect of radiating the heat generated from the semiconductor device 32 may be improved. Hence, the quality and the productivity of the semiconductor package may be improved.

### Modification of First Embodiment

In a modification of the first embodiment, the smooth convex surface part 34 of the radiator member 31 may be made of a material different from a material forming other portions of the radiator member 31. The smooth convex surface part 34 may be made of a metal or a resin that may withstand a pressing force applied from a press machine. When using the resin, the resin may be coated on a central region 36 of the radiating surface 31a of the radiator member 31 in FIG. 3C, formed into a smooth mountain shape, and cured for use in automatically aligning the bonding surface 31b of the radiator member 31 and the back surface 32a of the semiconductor device 32. After this automatic alignment, the resin may be removed from the radiating surface 31a. For example, the resin may be removed in order to planarize the radiating surface 31a and to facilitate bonding of radiator fins (not illustrated) having flat bonding surfaces onto the planarized radiating surface 31a of the radiator member 31.

According to this modification of the first embodiment, the radiating surface 31a of the radiator member 31 may be planarized after the automatic alignment. Hence, the radiator fins having the flat bonding surfaces may easily be bonded onto the planarized radiating surface 31a of the radiator member 31.

### Second Embodiment

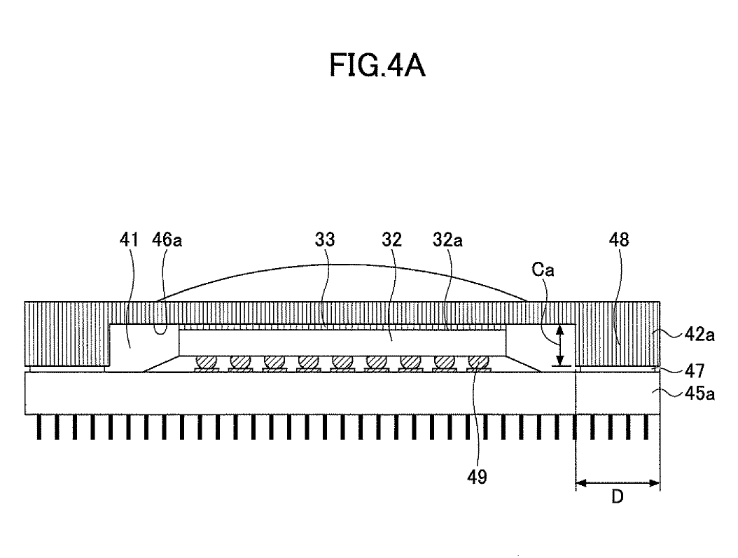

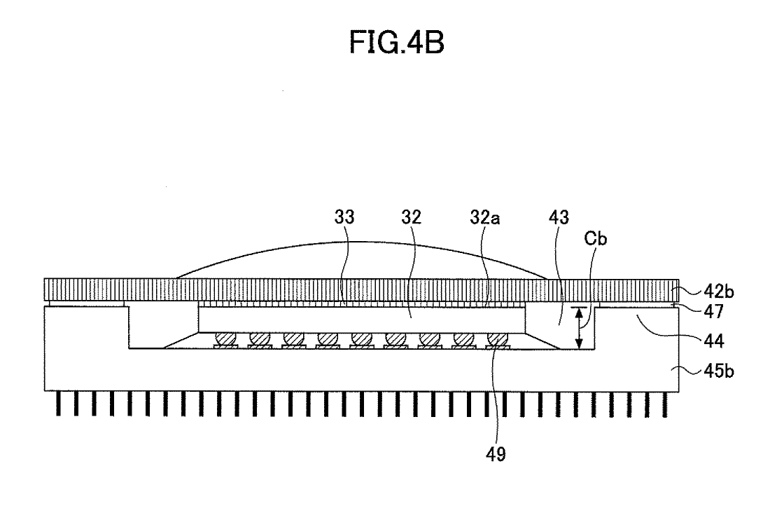

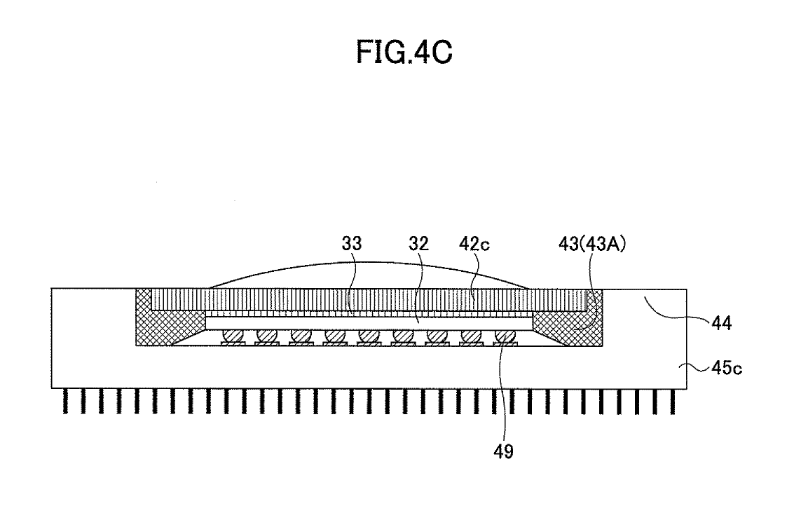

FIGS. 4A through 4C are cross sectional views for explaining a radiator member in a second embodiment of the present invention. In FIGS. 4A through 4C, those parts that are the same as those corresponding parts in FIGS. 3A through 3D are designated by the same reference numerals, and a description thereof will be omitted.

In this embodiment, the semiconductor package includes a wiring board 45 (one of 45a, 45b, and 45c), a semiconductor device 32, and a radiator member 42 (one of 42a, 42b, and 42c). The semiconductor device 32 mounted on the wiring board 45a via bumps 49 is accommodated within a recess 41 of the radiator member 42a or, the semiconductor device 32 mounted on the wiring board 45b or 45c via bumps 49 is accommodated within a cavity 43 of the wiring board 45b or 45c.

FIG. 4A illustrates a first example in which the recess 41 is formed in the radiator member 42a in order to secure a space for accommodating the semiconductor device 32. A bonding surface 46a of the radiator member 42a is bonded on the wiring board 45a via a bonding layer 47, and is bonded on a back surface (upper surface in FIG. 4A) 32a of the semiconductor device 32 via a bonding layer 33.

FIG. 4B illustrates a second example in which the cavity 43 is formed in the wiring board 45b in order to secure a space for accommodating the semiconductor device 32. The radiator member 42b is bonded on a peripheral part 44 of the wiring board 45b via a bonding layer 47, and is bonded on a back surface (upper surface in FIG. 4B) of the semiconductor device 32 via a bonding layer 33.

FIG. 4C illustrates a third example in which the cavity 43 is formed in the wiring board 45c in order to secure a space for accommodating the semiconductor device 32. The radiator member 42c is bonded on a peripheral part 44 of the wiring board 45b via a bonding layer 47, and is bonded on a back surface (upper surface in FIG. 4C) of the semiconductor device 32 via a bonding layer 33. Further, regions of the cavity 43, other than regions occupied by the semiconductor device 32 and the radiator member 42c, may be filled by a filler material 43A.

For example, the bonding layers 33 and 37 may be made of silicon polymer type resins.

In FIG. 4A, a width D of a peripheral wall 48 of the radiator member 42a, defining the recess 41, is 2 mm to 3 mm, for example. In addition, a depth Ca of the recess 41 is 0.5 mm to 0.9 mm, for example.

The depth Ca of the recess 41 in FIG. 4A may be set to a value smaller than a sum of a thickness of the semiconductor device 32, a thickness of the bonding layer 33, and a height of the bumps 49. By setting the depth Ca to such a value, the radiator member 42a may pivot and/or rotate about the peak of the smooth convex surface part thereof, without causing contact between the peripheral wall 48 of the radiator member 42a and the wiring board 45a, in order to easily arrange the back surface 32a of the semiconductor device 32 to become parallel to the bonding surface 46a of the radiator member 42a by the automatic alignment. Further, by setting the depth Ca to the value smaller than the sum described above, a gap may be formed between the peripheral wall 48 of the radiator member 42a and the wiring board 45a. However, the bonding layer 47 may sufficiently fill this gap by suitably setting the thickness of the bonding layer 47. As a result, the peripheral wall 48 of the radiator member 42a may be positively bonded to the wiring board 45a.

A depth Cb of the cavity 43 in FIG. 4B may be set to a value smaller than a sum of the thickness of the semiconductor device 32, the thickness of the bonding layer 33, and the height of the bumps 49. By setting the depth Cb to such a value, the radiator member 42b may pivot and/or rotate about the peak of the smooth convex surface part thereof, without causing contact between the radiator member 42b and the peripheral part 44 of the wiring board 45b, in order to easily arrange the back surface 32a of the semiconductor device 32 to become parallel to the bonding surface of the radiator member 42b by the automatic alignment. Further, by setting the depth Cb to the value smaller than the sum described above, a gap may be formed between the radiator member 42b and the peripheral part 44 of the wiring board 45b. However, the bonding layer 47 may sufficiently fill this gap by suitably setting the thickness of the bonding layer 47. As a result, the radiator member 42b may be positively bonded to the peripheral part 44 of the wiring board 45b.

An automatic alignment, similar to the automatic alignment achieved in FIG. 4B, may be achieved in FIG. 4C.

The wiring boards 45a, 45b, and 45c in FIGS. 4A, 4B and 4C employ the PGA, however, other formats may be used, including the LGA and the BGA. In addition, the wiring boards 45a, 45b, and 45c may be formed by a mother board or the like that is often used in electronic equipments.

When the semiconductor device is accommodated within a closed space formed by the recess of the radiator member or by the cavity of the wiring board, it may be difficult to measure a distance between the back surface of the semiconductor device and the opposing, bonding surface of the radiator member. Further, it may be difficult to set a direction in which the radiator member or the wiring board is to be pressed. According to this second embodiment, however, the automatic alignment may be made with ease using the radiator member having the smooth convex surface part with the peak. As a result, a series of bonding processes may be carried out with a high precision, and the semiconductor package may be produced to have a sufficient heat radiating effect. Hence, the quality and the productivity of the semiconductor package may be improved.

### Third Embodiment

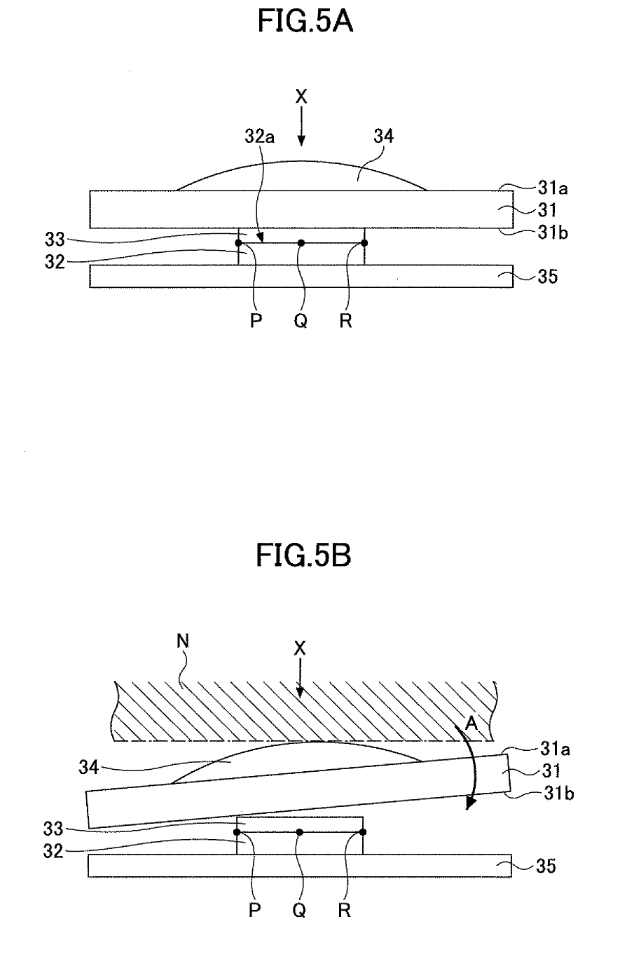

FIGS. 5A and 5B are side views for explaining the automatic alignment in the third embodiment of the present invention. In FIGS. 5A and 5B, those parts that are the same as those corresponding parts in FIGS. 3A through 3D are designated by the same reference numerals, and a description thereof will be omitted.

The automatic alignment may use the smooth convex surface part of the radiator member in order to self-align the bonding surface of the radiator member and the opposing, back surface of the semiconductor device to become parallel to each other. This automatic alignment may require a pressing force of the press machine, but may not require a measuring mechanism, a control mechanism or the like to be provided on the press machine.

FIG. 5A illustrates a state where the bonding surface 31b of the radiator member 31 and the back surface 32a of the semiconductor device 32 are parallel to each other.

On the other hand, FIG. 5B illustrates a state where the bonding surface 31b of the radiator member 31 and the back surface 32a of the semiconductor device 32 are not parallel to each other. In this state, amongst a left end point P, a center point Q, and a right end point R on the back surface 32a of the semiconductor device 32, the left end point P contacts (or hits) the bonding surface 31b of the radiator member 31 via the bonding layer 33. This contact at one end occurs because the bonding surface 31b and the back surface 32a are not parallel to each other due to causes which may include an uneven thickness of the radiator member 31 or, an error in the direction of the pressing force applied by the press machine on the radiator member or the wiring board. It may be difficult to solve each of the causes independently during each production stage of the semiconductor package. In addition, if the semiconductor device and the radiator member are bonded in a stage where the contact at one end occurs, a void may be generated in a space where the semiconductor device and the radiator member are not bonded together. When such a void is generated, a sufficient heat radiating effect may not be obtained, and a sufficient bonding strength may not be achieved between the semiconductor device and the radiator member. Accordingly, it is desirable to avoid the contact at one end between the semiconductor device and the radiator member, and to positively align the semiconductor device and the radiator member to become parallel to each other.

FIG. 5B illustrates a state where the semiconductor device 32 and the radiator member 31 are in contact at one end. When the pressing force is applied in a direction X, the back surface 32a of the semiconductor device 32 is pushed at the left end point P via the bonding layer 33. As a result, the thickness of the bonding layer 33 having fluidity decreases at the left end point P, and the radiator member 31 and the semiconductor device 32 substantially make contact with each other at the left end point P. Consequently, a relatively strong reaction occurs between the radiator member 31 and the semiconductor device 32 at the left end point P. On the other hand, the reaction between the radiator member 31 and the semiconductor device 32 does not occur at the center point Q and the right end point R, and substantially no load is applied at the center point Q and the right end point R. Because the radiator member 31 as a whole is pushed in the direction X by a pressing plate N of the press machine, the coupling (or inertia coupling) of the radiator member 31 becomes unbalanced.

The unbalanced coupling of the radiator member 31 causes the radiator member 31 to pivot and/or rotate in a direction A about the left end point P. This pivoting and/or rotating motion of the radiator member 31 aligns the bonding surface 31b of the radiator member 31 and the back surface 32a of the semiconductor device 32 in a direction to become parallel to each other until the coupling of the radiator member 31 becomes balanced. In other words, the alignment achieved by the pivoting and/or rotating motion of the radiator member 31 continues until the coupling of the radiator member 31 becomes balanced and the bonding surface 31b of the radiator member 31 and the back surface 32a of the semiconductor device 32 become parallel to each other, as illustrated in FIG. 5A. In the parallel state illustrated in FIG. 5A, the pressure (or stress) generated in the direction X is substantially the same at each of the points P, Q and R, and the coupling of the radiator member 31 is substantially balanced in this state. Furthermore, the distance between the bonding surface 31b of the radiator member 31 and the back surface 32a of the semiconductor device 32 may be determined by the pressing force of the pressing plate N of the press machine in the direction X, depending on properties such as the viscosity of the bonding layer 33. Hence, the automatic alignment of the radiator member 31 and the semiconductor device 32 for parallelism may be carried out without requiring a measuring mechanism, a control mechanism or the like to be provided on the press machine.

It is assumed that the bonding layer 33 has fluidity in the description given above with respect to the behavior of the radiator member 31. However, the bonding layer 33 may be made of a relatively hard material, such as a metal, because the coupling of the radiator member 31 may be balanced in a similar manner, and the automatic alignment of the radiator member 31 and the semiconductor device 32 may be achieved in a similar manner.

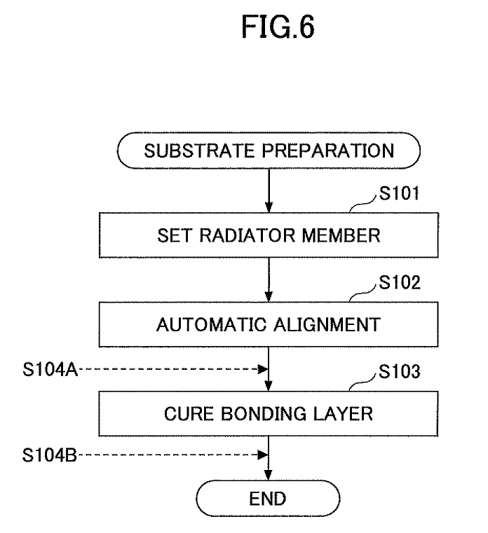

FIG. 6 is a flow chart for explaining a method of producing the semiconductor package in the third embodiment of the present invention. The semiconductor package production process illustrated in FIG. 6 includes a radiator member setting step (or process) S101, an automatic alignment step (or process) S102, and a bonding layer during step (or process) S103. It is assumed for the sake of convenience that the semiconductor package illustrated in FIG. 3A is produced.

The wiring board 35 mounted with the semiconductor device 32 is prepared in order to carry out the step S101. The following processes are carried out in the step S101. First, the bonding layer 33 is coated on the back surface 32a of the semiconductor device 32. The TIM used for the bonding layer 33 may be a silicon polymer resin, for example. A known resin coating technique may be employed in order to coat the TIM material and cause the TIM material to become semi-cured (or partially cured). Then, the radiator member 31 having the smooth convex surface part 34 is set on the bonding layer 33 provided on the semiconductor device 32. The TIM used for the bonding layer 33 is not limited to resins, and may include metals such as indium, alloys such as indium alloys, carbon-containing resins, and carbon-containing metals or alloys. Furthermore, relatively hard materials having substantially no fluidity, such as metals, may be used for the TIM of the bonding layer 33.

In the step S102, the press machine presses the radiator member 31 towards the semiconductor device 32, in order to carry out the above described automatic alignment of the radiator member 31 and the semiconductor device 32.

In the step S103, a known resin curing technique is employed in order to cure the bonding layer 33.

In a case where a bonding layer 47 is provided between radiator member 42a and the wiring board 45a as illustrated in FIG. 4A or, between the radiator member 42b and the wiring board 45b as illustrated in FIG. 4B, in addition to the bonding layer 33 between the radiator member 42a or 42b and the semiconductor device 32, the automatic alignment may be carried out while securing a sufficient thickness for the bonding layer 47. For example, the thickness of the bonding layer 47 may be 0.2 mm to 0.25 mm.

According to the third embodiment, the automatic alignment of the radiator member and the semiconductor device may be carried out without requiring a measuring mechanism, a control mechanism or the like to be provided on the press machine. For this reason, the productivity and the quality of the semiconductor package may be improved.

### Modification of Third Embodiment

In a modification of the third embodiment, convex surface part 34 may be removed after the automatic alignment of the step S102 described above. For example, a step S104A may be carried out to remove the convex surface part 34 after the step S102 and before the bonding layer 33 is cured in the step S103, as indicated by dotted lines in FIG. 6. Alternatively, a step S104B may be carried out to remove the convex surface part 34 after the bonding layer 33 is cured in the step S103, as indicated by dotted lines in FIG. 6.

### Fourth Embodiment

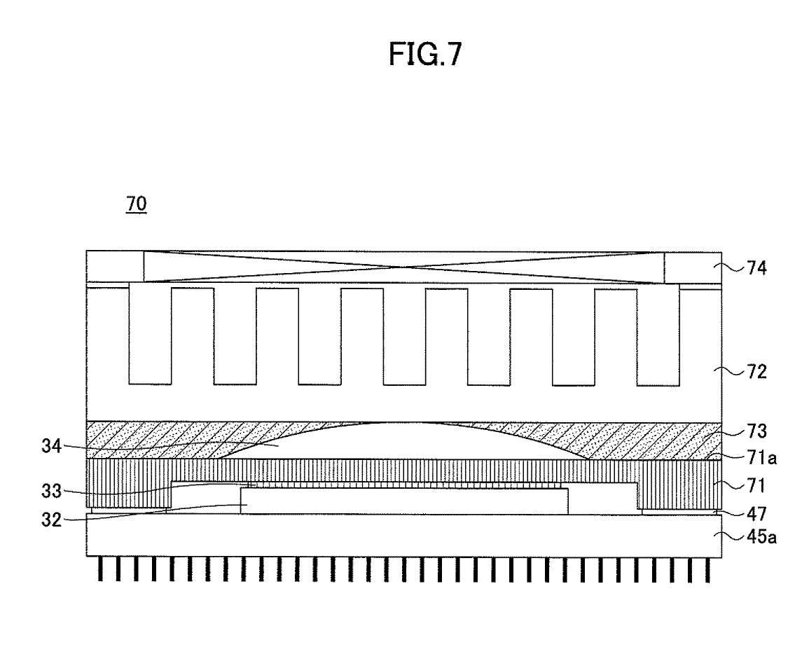

FIG. 7 is a cross sectional view illustrating a semiconductor package in a fourth embodiment of the present invention. In FIG. 7, those parts that are the same as those corresponding parts in FIG. 4A are designated by the same reference numerals, and a description thereof will be omitted. Further, the illustration of the bumps 49 and the like is omitted in FIG. 7 for the sake of convenience.

A semiconductor package 70 illustrated in FIG. 7 includes radiator fins 72 provided on a radiator member 71 via a bonding layer 73. The provision of the radiator fins 72 may further improve the heat radiating efficiency of the radiator member 71. The shape and the material used for the radiator fins 72 may be selected arbitrarily, from known shapes and materials, for example. The bonding layer 73 provided on a radiating surface 71a of the radiator member 71 may be formed by a sheet type or a gel type TIM, such as a silicon polymer resin. Cooling fins 74 may further be provided on the radiator fins 72 as illustrated in FIG. 7, in order to further improve the heat radiating efficiency by forced convection of air or the like.

According to the fourth embodiment, the heat radiating efficiency may further be improved by the provision of the radiator fins 72, compared to a case where no radiator fins 72 are provided on the radiator member 73. As a result, the performance of the semiconductor package 70 may further be improved.

### Fifth Embodiment

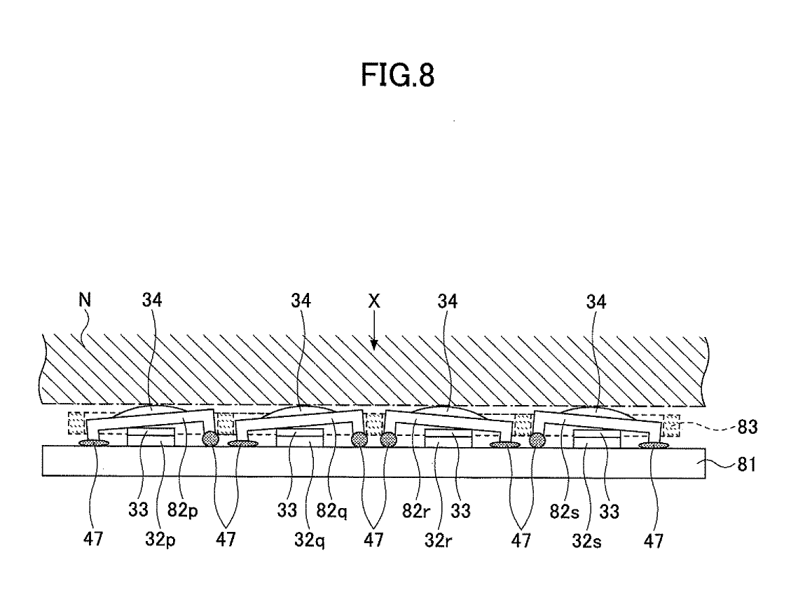

FIG. 8 is a side view for explaining the automatic alignment in a fifth embodiment of the present invention. In FIG. 8, those parts that are the same as those corresponding parts in FIG. 4A are designated by the same reference numerals, and a description thereof will be omitted.

The semiconductor package production process for this fifth embodiment may be similar to that described above in conjunction with FIG. 6, except that a plurality of semiconductor elements are arranged two-dimensionally on the wiring board.

In FIG. 8, a plurality of semiconductor devices 32p, 32q, 32r, and 32s are provided on a wiring board 81, and a plurality of radiator members 82p, 82q, 82r, and 82s are provided on the corresponding semiconductor devices 32p, 32q, 32r, and 32s. In a state illustrated in FIG. 8, the pressing plate N of the press machine presses the smooth convex surface parts 34 of each of the radiator members 82p, 82q, 82r, and 82s in the direction X, in order to automatically align the radiator members 82p, 82q, 82r, and 82s and the semiconductor devices 32p, 32q, 32r, and 32s, simultaneously.

The automatic alignment of the radiator members 82p, 82q, 82r, and 82s and the semiconductor devices 32p, 32q, 32r, and 32s for achieving the parallelism may be carried out in a similar manner as the third embodiment described above in conjunction with FIGS. 5A and 5B.

A retainer (or a support frame) 83 indicated by phantom lines in FIG. 8 may be used when pressing the smooth convex surface parts 34 of each of the radiator members 82p, 82q, 82r, and 82s in the direction X by the pressing plate N of the press machine, in order to prevent the radiator members 82p, 82q, 82r, and 82s from sliding in a direction parallel to the surface (or mounting surface, which is the upper surface in FIG. 8) of the wiring board 81 by restricting movements thereof.

According to the fifth embodiment, it is possible to automatically align and bond a plurality of radiator members and a plurality of semiconductor devices, simultaneously. As a result, the productivity and the production cost of the semiconductor package may be improved.

Further, the present invention is not limited to these embodiments, but various variations and modifications may be made without departing from the scope of the present invention.

What is claimed is:

1. A method of producing a semiconductor package, comprising:
setting a radiator member on a semiconductor device that is mounted on a wiring board, said radiator member having a convex surface part on at least a part of a first surface thereof opposite to a second surface thereof to be bonded to the semiconductor device; and
pressing the convex surface part of the radiator member towards the semiconductor device in order to align the radiator member and the semiconductor device automatically and to become substantially parallel to each other.

2. The method of producing the semiconductor package as claimed in claim 1, further comprising:
bonding the second surface of the radiator member on a back surface of the semiconductor device, opposite to a mounting surface thereof mounted on the wiring board, using a bonding layer.

3. The method of producing the semiconductor package as claimed in claim 2, wherein said pressing automatically aligns the second surface of the radiator member to become substantially parallel to the back surface of the semiconductor device.

4. The method of producing the semiconductor package as claimed in claim 2, wherein the convex surface part of the radiator member is made of a material different from a material forming other portions of the radiator member.

5. The method of producing the semiconductor package as claimed in claim 4, further comprising:
removing the convex surface part after said bonding.

6. The method of producing the semiconductor package as claimed in claim 2, wherein said setting sets the radiator member on the semiconductor device in a state where the semiconductor device is accommodated within a recess of the radiator member.

7. The method of producing the semiconductor package as claimed in claim 2, wherein said setting sets the radiator member on the semiconductor device in a state where the semiconductor device is accommodated within a cavity of the wiring board.

8. The method of producing the semiconductor package as claimed in claim 2, wherein said setting, said pressing, and said bonding are carried out simultaneously with respect to a plurality of radiator members and a plurality of semiconductor devices.

9. The method of producing the semiconductor package as claimed in claim 8, wherein said pressing uses a retainer for restricting movements of the plurality of radiator members in a direction parallel to a surface of the wiring board on which the plurality of semiconductor devices are mounted.

10. A semiconductor package comprising:
a wiring board;
a semiconductor device mounted on the wiring board; and
a radiator member provided on the semiconductor device,
wherein the radiator member includes a convex surface part on at least a part of a first surface thereof opposite to a second surface thereof bonded to the semiconductor device.

11. The semiconductor package as claimed in claim 10, wherein the convex surface part is provided in a central region of the first surface of the radiator member.

12. The semiconductor package as claimed in claim 11, wherein the convex surface part is made of a material different from a material forming other portions of the radiator member.

13. The semiconductor package as claimed in claim 11, further comprising:
a first bonding layer provided between the radiator member and the semiconductor device.

14. The semiconductor package as claimed in claim 13, further comprising:
a second bonding layer provided between the radiator member and the wiring board.

15. The semiconductor device as claimed in claim 11, wherein the radiator member includes a recess configured to accommodate therein the semiconductor device.

16. The semiconductor device as claimed in claim 15, further comprising:
a first bonding layer provided between the radiator member and the semiconductor device; and
a second bonding layer provided between the radiator member and the wiring board.

17. The semiconductor device as claimed in claim 11, wherein the wiring board includes a cavity configured to accommodate therein the semiconductor device.

18. The semiconductor device as claimed in claim 17, further comprising:
a first bonding layer provided between the radiator member and the semiconductor device; and
a second bonding layer provided between the radiator member and the wiring board.
